(19) United States
(12) Patent Application Publication
(10) Pub. No.: US 2016/0359141 A1
(43) Pub. Date: Dec. 8, 2016

(54) ORGANIC LIGHT-EMITTING DISPLAY APPARATUS

(71) Applicant: Samsung Display Co., Ltd., Yongin-si (KR)

(72) Inventors: Deokchan Yoon, Yongin-si (KR); Kiehyun Nam, Yongin-si (KR); Heungkyoon Lim, Yongin-si (KR)

(21) Appl. No.: 15/040,867

(22) Filed: Feb. 10, 2016

(30) Foreign Application Priority Data
Jun. 3, 2015 (KR) 10-2015-0078665

(51) Int. Cl. H01L 51/52

(52) U.S. Cl. CPC H01L 51/5268; H01L 51/5253

(57) ABSTRACT

An organic light-emitting display apparatus includes: a substrate; an organic light-emitting diode on the substrate; and a thin film encapsulation portion on the organic light-emitting diode, and including a first inorganic layer, a planarization layer including a silicone-based organic material, and a second inorganic layer, wherein a hardness of the planarization layer is about 0.1 GPa to about 5 GPa.

### CROSS-REFERENCE TO RELATED APPLICATION

This application claims priority to and the benefit of Korean Patent Application No. 10-2015-0078665, filed on Jun. 3, 2015, in the Korean Intellectual Property Office, the disclosure of which is incorporated herein in its entirety by reference.

### BACKGROUND

1. Field

One or more exemplary embodiments of the present invention relate to an organic light-emitting display apparatus.

2. Description of the Related Art

Organic light-emitting display apparatuses are self-emitting type display apparatuses including organic light-emitting diodes (OLEDs). Each OLED includes a hole injection electrode, an electron injection electrode, and an organic emission layer that is between the hole injection electrode and electron injection electrode. In the organic light-emitting display apparatus, excitons, which are generated when holes injected from the hole injection electrode and electrons injected from the electron injection electrode are united in the organic emission layer, emit light when falling from an excited state to a ground state.

Organic light-emitting display apparatuses that are self-emitting type display apparatuses require no additional light sources, and thus, they may be driven by a low voltage, and may be formed to be relatively thin and relatively light. Also, organic light-emitting display apparatuses have good characteristics, such as wide viewing angles, high contrast, and rapid response rates, which have drawn attention to the organic light-emitting display apparatuses as next generation display apparatuses.

### SUMMARY

One or more exemplary embodiments of the present invention include an organic light-emitting display apparatus.

Additional aspects are set forth in part in the description which follows and, in part, will be apparent from the description, or may be learned by practice of the presented embodiments.

According to one or more exemplary embodiments of the present invention, an organic light-emitting display apparatus includes: a substrate; an organic light-emitting diode on the substrate; and a thin film encapsulation portion on the organic light-emitting diode and including a first inorganic layer, a planarization layer including a silicone-based organic material, and a second inorganic layer, wherein a hardness of the planarization layer is about 0.1 GPa to about 5 GPa.

A modulus of elasticity of the planarization layer may be about 0.5 GPa to about 10 GPa.

A thickness of the planarization layer may be about 0.01 mm to about 0.1 mm.

The planarization layer may include particle-shaped materials.

The particle-shaped materials may be inorganic materials.

The particle-shaped materials may be scatter materials.

The planarization layer may include phenyl-based silicone.

The planarization layer may include polydimethylsiloxane including silsesquioxane.

The thin film encapsulation portion may further include an organic layer between the first inorganic layer and the planarization layer, and the organic layer may include an acryl-based material.

The planarization layer may include a planarization dam at both ends of the first inorganic layer, wherein the thin film encapsulation portion may further include an organic layer between the planarization dam and the second inorganic layer, and the organic layer may include an acryl-based material.

According to one or more exemplary embodiments of the present invention, an organic light-emitting display apparatus includes: a substrate; an organic light-emitting diode on the substrate; and a thin film encapsulation portion on the organic light-emitting diode that includes a first inorganic layer, a planarization layer including a silicone-based organic material, and a second inorganic layer, wherein a modulus of elasticity of the planarization layer is about 0.5 GPa to about 10 GPa.

According to one or more exemplary embodiments, an organic light-emitting display apparatus includes: a substrate; an organic light-emitting diode on the substrate; and a thin film encapsulation portion on the organic light-emitting diode, the thin film encapsulation portion including a first inorganic layer, a planarization layer including a silicone-based organic material, and a second inorganic layer, wherein a modulus of elasticity of the planarization layer is about 0.5 to about 10 GPa, and a hardness of the planarization layer is about 0.1 GPa to about 5 GPa.

According to one or more exemplary embodiments of the present invention, an organic light-emitting display apparatus includes: a substrate; an organic light-emitting diode on the substrate; and a thin film encapsulation portion on the organic light-emitting diode and including a first inorganic layer, a second inorganic layer, and a planarization dam between the first and second inorganic layers, the planarization dam including a high strength silicone-based organic material, and wherein a hardness of the planarization dam is about 0.1 GPa to about 5 GPa.

A modulus of elasticity of the planarization dam may be about 0.5 GPa to about 10 GPa.

The thin film encapsulation portion may further include an organic layer between the planarization dam and the second inorganic layer, and the organic layer may include an acryl-based material.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a cross-sectional view of a portion of an organic light-emitting display apparatus according to one or more exemplary embodiments of the present invention;

FIG. 2 is a cross-sectional view of an organic light-emitting display apparatus according to one or more exemplary embodiments of the present invention;

FIG. 3 is a cross-sectional view of an organic light-emitting display apparatus according to one or more exemplary embodiments of the present invention; and

FIG. 4 is a cross-sectional view of an organic light-emitting display apparatus according to one or more exemplary embodiments of the present invention.

### DETAILED DESCRIPTION

Reference is made herein to exemplary embodiments of the present invention, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figures, to explain aspects of the present invention. As used herein, the term “and/or” includes any and all combinations of one or more of the associated listed items. Expressions such as “at least one of,” when preceding a list of elements, modify the entire list of elements and do not modify the individual elements of the list.

It will be understood that although the terms “first,” “second,” etc. may be used herein to describe various components, these components should not be limited by these terms. These terms are merely used to distinguish one component from another.

As used herein, the singular forms “a” and “an” are intended to include the plural forms as well, unless the context clearly indicates otherwise.

It will be further understood that the terms “comprises,” “comprising,” “includes,” and/or “including” used herein specify the presence of stated features or components, but do not preclude the presence or addition of one or more other features or components.

It will be understood that when a layer, region, or component is referred to as being “ on” or “connected to” another layer, region, or component, it can be directly on or connected to the other layer, region, or component, or one or more intervening layers, regions, or components may be present. That is, for example, intervening layers, regions, or components may be present. In addition, it will also be understood that when an element or layer is referred to as being “between” two elements or layers, it can be the only element or layer between the two elements or layers, or one or more intervening elements or layers may also be present.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Sizes of elements in the drawings may be exaggerated for convenience of explanation. In other words, because sizes and thicknesses of components in the drawings may be arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

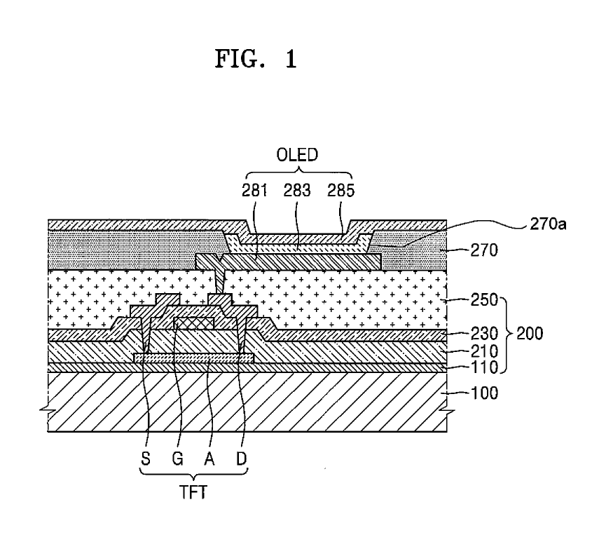

FIG. 1 is a cross-sectional view of an organic light-emitting display apparatus according to one or more exemplary embodiments of the present invention. As illustrated in FIG. 1, the organic light-emitting display apparatus may include a thin film transistor TFT and an organic light-emitting diode OLED which are provided on a substrate 100. While only one thin film transistor TFT and one organic light-emitting diode OLED are illustrated in FIG. 1, an organic light-emitting display apparatus typically includes hundreds of thousands or more thin film transistors and organic light-emitting diodes.

As illustrated in FIG. 1, a buffer layer 110 may be formed on the substrate 100. The buffer layer 110 may prevent (or substantially prevent) diffusion of impurity ions and/or penetration of water and/or external bodies into the organic light-emitting diode OLED and may function as a barrier layer and/or a blocking layer for planarizing a surface of the substrate 100.

The thin film transistor TFT may be formed on the buffer layer 110. A semiconductor layer A of the thin film transistor TFT may include polysilicon and may include a channel area which is not doped with impurities, and a source area and a drain area which are doped with impurities at respective sides of the channel area. Here, the impurities may vary depending on a type of thin film transistor that is used, and may be n-type impurities or p-type impurities.

After the semiconductor layer A is formed, a gate insulating layer 210 may be formed above the semiconductor layer A throughout (or over) the substrate 100 (e.g., over the entire substrate or over substantially the entire substrate). The gate insulating layer 210 may include a single layer or multiple layers including an inorganic material, such as silicon oxide and/or silicon nitride. The gate insulating layer 210 may insulate a gate electrode G, which is disposed above the semiconductor layer A, from the semiconductor layer A.

After the gate insulating layer 210 is formed, the gate electrode G may be formed on the gate insulating layer 210. The gate electrode G may be formed by a photolithography process and/or by an etching process, or any other suitable process.

The gate electrode G may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

After the gate electrode G is formed, a first interlayer insulating layer 230 may be formed throughout (or over) the substrate 100.

The first interlayer insulating layer 230 may include an inorganic material. For example, the first interlayer insulating layer 230 may be metal oxide and/or metal nitride. In more detail, the inorganic material may include, for example, SiO₂, SiNx, SiON, Al₂O₃, TiO₂, Ta₂O₅, HfO₂, and/or ZrO₂.

The first interlayer insulating layer 230 may include a single layer or multiple layers including an inorganic material, such as SiOx and/or SiNx. In some embodiments, the first interlayer insulating layer 230 may include a double-layer structure of SiOx/SiNy or SiNx/SiOy.

A source electrode S and a drain electrode D of the thin film transistor TFT may be disposed on the first interlayer insulating layer 230.

The source electrode S and the drain electrode D may include at least one metal selected from Al, Pt, Pd, Ag, Mg, Au, Ni, Nd, Ir, Cr, Li, Ca, Mo, Ti, W, and Cu.

Referring to FIG. 1, a via layer 250 is formed on the substrate 100 (e.g., on the entire substrate 100) so as to cover the source electrode S and the drain electrode D. A pixel electrode 281 may be formed on the via layer 250. According to the exemplary embodiment illustrated in FIG. 1, the pixel electrode 281 is connected to the drain electrode D via a via hole.

The via layer 250 may include an insulating material. For example, the via layer 250 may include a single layer or multiple layers by using an inorganic material, an organic material, and/or an organic/inorganic compound. The via layer 250 may be formed by using one or more deposition methods. In some embodiments, a planarization layer may be on (adjacent) the via layer 250 and may include at least one of a polyacrylate resin, an epoxy resin, a phenolic resin, a polyamide resin, a polyimide resin, an unsaturated polyester resin, a polyphenyl ether resin, a polyphenylene sulfide resin, and/or benzocyclobutene (BCB).

As illustrated in FIG. 1, the organic light-emitting diode OLED may be on the via layer 250. The organic light-emitting diode OLED includes a pixel electrode 281, an intermediate layer 283 including an organic emission layer, and an opposite electrode 285. Also, the organic light-emitting diode OLED may further include a pixel-defining layer 270.

The pixel electrode 281 and/or the opposite electrode 285 may be provided as a transparent electrode or a reflection electrode. When the pixel electrode 281 and/or the opposite electrode 285 include the transparent electrode, the pixel electrode 281 and/or the opposite electrode 285 may include ITO, IZO, ZnO, and/or In₂O₃, and when the pixel electrode 281 and/or the opposite electrode 285 include the reflection electrode, the pixel electrode 281 and/or the opposite electrode 285 may include a reflective layer including Ag, Mg, Al, Pt, Pd, Au, Ni, Nd, Ir, Cr, and/or a compound thereof, and a transparent layer including ITO, IZO, ZnO, and/or IN₂O₃. In some embodiments, the pixel electrode 281 and/or the opposite electrode 285 may have an ITO/Ag/ITO structure.

As illustrated in FIG. 1, the pixel-defining layer 270 may define a pixel area and a non-pixel area. The pixel-defining layer 270 may include an opening 270a that partially exposes the pixel electrode 281 and may cover the entire substrate 100. The intermediate layer 283, which is described further below, may be formed in the opening 270a so that the opening 270a may correspond to an actual pixel area.

The pixel electrode 281, the intermediate layer 283, and the opposite electrode 285 form the organic light-emitting diode OLED. Holes and electrons respectively injected from the pixel electrode 281 and the opposite electrode 285 of the organic light-emitting diode OLED are combined in the organic emission layer of the intermediate layer 283 to emit light.

The intermediate layer 283 may include the organic emission layer. In some exemplary embodiments, the intermediate layer 283 may include the organic emission layer, and may further include at least one of a hole injection layer (HIL), a hole transport layer (HTL), an electron transport layer (ETL), and an electron injection layer (EIL). However, the present invention is not limited thereto, and the intermediate layer 283 may include the organic emission layer and may further include other various layers (e.g., various functional layers).

The opposite electrode 285 is formed on the intermediate layer 283. The opposite electrode 285 forms an electric field with the pixel electrode 281 so that the intermediate layer 283 emits light. The pixel electrode 281 may be patterned per pixel, and the opposite electrode 285 may be formed such that a common voltage is applied to each of the pixels.

The pixel electrode 281 may function as an anode and the opposite electrode 285 may function as a cathode. However, the present invention is not limited thereto. For example, the pixel electrode 281 may function as a cathode and the opposite electrode 285 may function as an anode.

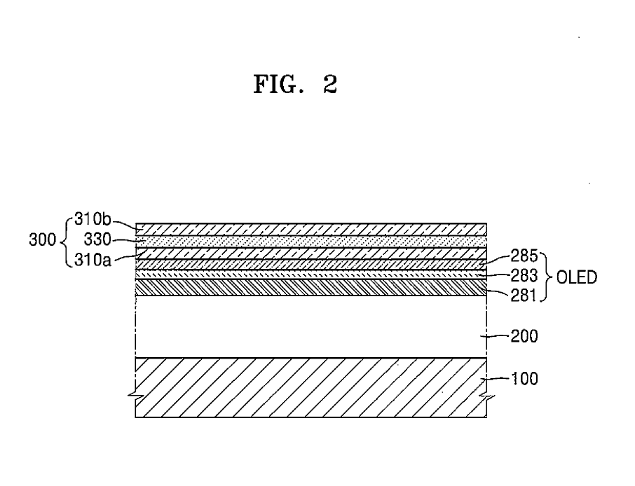

FIG. 2 is a cross-sectional view of an organic light-emitting display apparatus according to one or more exemplary embodiments of the present invention. As illustrated in FIG. 2, the organic light-emitting display apparatus may include the substrate 100, a display unit 200 provided on the substrate 100, the organic light-emitting diode OLED, and a thin film encapsulation portion 300 that encapsulates the organic light-emitting diode OLED.

The thin film encapsulation portion 300 may have a structure in which a plurality of thin film layers are stacked, for example, a structure in which inorganic layers (e.g., first and second inorganic layers 310a and 310b), and a planarization layer 330 are alternately stacked.

In the organic light-emitting display apparatus according to one or more exemplary embodiments of the present invention, the thin film encapsulation portion 300 may include the first inorganic layer 310a, the planarization layer 330, and the second inorganic layer 330b, which are sequentially stacked. In some exemplary embodiments, the thin film encapsulation portion 300 may include three stacked thin film layers. However, the number of thin film layers is not limited thereto.

The first and second inorganic layers 310a and 310b may prevent or reduce the likelihood of penetration of oxygen and/or water into the organic light-emitting diode OLED, and the planarization layer 330 may absorb stress of the first and second inorganic layers 310a and 310b to contribute to the flexibility of the first and second inorganic layers 310a and 310b.

The first and second inorganic layers 310a and 310b may each be a single layer or stacked layers including metal oxide and/or metal nitride. For example, the first and second inorganic layers 310a and 310b may include any one of SiNₓ, Al₂O₃, SiO₂, and TiO₂.

The planarization layer 330 may be a single layer or stacked layers including a silicone-based organic material.

The silicone-based organic material may include a bi-functional material, a tri-functional material, and/or a polymer thereof including siloxane groups, such as thermosetting polydimethylsiloxane, thermosetting polydimethylsiloxane including silsesquioxane, polyphenylmethylsiloxane or a copolymer thereof, and/or methylsiloxane, for example. However, the silicone-based organic material is not limited thereto.

According to an organic light-emitting display apparatus of the prior art, a planarization layer of a thin film encapsulating structure may include an acryl-based material, such as polyacrylate, etc. As such, the strength of the planarization layer decreases to increase the flexibility of the planarization layer. However, stress concentrates in an inorganic layer thereof, and thus, wrinkles and haze may occur.

A haze phenomenon occurs when stress concentrates in the inorganic layer on the planarization layer such that a surface of the planarization layer below the inorganic layer, which is not adapted to bear stress applied thereto, creates wrinkles in the planarization layer. Due to the haze phenomenon, a transparent planarization layer may become gray.

Also, in the case of the planarization layer including the acryl-based material, the hardness thereof is low. As such, damage to the planarization layer may occur by CVD plasma in a process of depositing the inorganic layer.

However, in the organic light-emitting display apparatus according to one or more exemplary embodiments of the present invention, the planarization layer 330 includes a silicone-based organic material having a high strength, and thus, the CVD plasma damage or the stress to the inorganic layer may be prevented (or the likelihood thereof may be reduced).

In addition, the planarization layer including the acryl-based material according to a conventional organic light-emitting display apparatus has a low viscosity, and thus, it was very difficult to form the planarization layer to have a thickness equal to or greater than 10 μm.

Thus, there was a need to form the planarization layer more than twice, in order to increase the reliability of the organic light-emitting diode OLED by blocking external oxygen/water. Accordingly, additional manufacturing processes were desired.

Also, in order to reduce the number of times the planarization layer is formed, a dam structure was formed at a boundary portion of the substrate in order to prevent overflow of the planarization layer, which has low viscosity. Accordingly, manufacturing time and costs were increased due to the additional manufacturing processes.

However, in the organic light-emitting display apparatus according to one or more exemplary embodiments of the present invention, the planarization layer 330 includes the silicone-based organic material having a high viscosity, and thus, the planarization layer 330 may be formed to have a predetermined thickness.

In some exemplary embodiments of the organic light-emitting display apparatus, the planarization layer 330 may be formed to have a thickness of about 0.01 mm to about 0.1 mm. However, the planarization layer 330 is not limited thereto.

Because the planarization layer 330 includes the high viscosity silicone-based organic material, unlike the planarization layer of the conventional organic light-emitting display apparatuses, the planarization layer 330 may be formed to have a relatively large thickness. Accordingly, even when only one planarization layer 330 is formed, as illustrated in FIG. 2, the planarization layer 330 may block the organic light-emitting diode OLED from external oxygen/water, thereby increasing the reliability of the organic light-emitting diode OLED.

Therefore, in the organic light-emitting display apparatus according to one or more exemplary embodiments of the present invention, it is not necessary to alternately form additional planarization layers 330, and one planarization layer 330 may sufficiently protect the organic light-emitting diode OLED.

Also, in the organic light-emitting display apparatus according to one or more exemplary embodiments of the present invention, the planarization layer 330 includes the silicone-based organic material which has a high viscosity, and thus, it is unlikely that the planarization layer 330 will overflow, so an additional dam structure does not need to be formed at a boundary portion of the substrate 100. Thus, manufacturing time and costs of the organic light-emitting display apparatus may be reduced.

As described above, in the conventional organic light-emitting display apparatuses, the planarization layer includes the acryl-based material having a low viscosity, and thus, the planarization layer is also deposited at unnecessary portions of the substrate because the viscosity of the planarization layer is low. Thus, there is a lot of loss of materials, resulting in relatively high manufacturing costs to manufacture the organic light-emitting display apparatus.

However, in the organic light-emitting display apparatus according one or more exemplary embodiments of the present invention, the planarization layer 330 includes the high viscosity silicone-based organic material, and thus, the likelihood of depositing materials at unnecessary portions of the substrate 100 when the planarization layer 330 is formed may be reduced.

Also, in the conventional organic light-emitting display apparatuses, because the planarization layer includes the low viscosity acryl-based material, as described above, it is difficult to add particles having certain functions, such as a scatter material.

However, in the organic light-emitting display apparatus according to one or more exemplary embodiments of the present invention, because the planarization layer 330 includes the high viscosity silicone-based organic material, the planarization layer 330 may be formed to have a relatively large thickness. Accordingly, particles having certain functions, such as a scatter material, may be added to the planarization layer 330 to increase the efficiency of the organic light-emitting display apparatus.

Also, in the conventional organic light-emitting display apparatuses, because the planarization layer includes the low viscosity acryl-based material, as described above, even if impurity particles are included in the inorganic layer below the planarization layer, the planarization layer may not cover the impurity particles. That is, the planarization layer including the low viscosity acryl-based material has a low viscosity and thus it may be hard to form the planarization layer to have a relatively small thickness that is equal to or greater than 10 μm. As such, if particles such as external impurities are included below the planarization layer, the planarization layer may not cover the impurity particles.

This may result in the planarization layer not planarizing the thin film encapsulating layer.

However, in the organic light-emitting display apparatus according to one or more exemplary embodiments of the present invention, because the planarization layer 330 includes the high viscosity silicone-based organic material, the planarization layer 330 may be formed to have a relatively large thickness. Thus, even if impurity particles are included below the planarization layer, the planarization layer may sufficiently cover the impurity particles.

As described above, in the organic light-emitting display apparatus according to one or more exemplary embodiments of the present invention, the planarization layer 330 of the thin film encapsulation portion 300 includes the silicone-based organic material, and thus, the planarization layer 330 may be formed to have a high strength (or hardness) and a high viscosity.

The hardness of the planarization layer 330 of the organic light-emitting display apparatus according to one or more exemplary embodiments of the present invention may be about 0.1 GPa to about 5 GPa. As such, because the planarization layer 330 is formed to have a relatively high hardness, a phenomenon, such as stress, CVD plasma damage, etc. of the inorganic layer may be reduced.

Also, a modulus of elasticity (Young's modulus) of the planarization layer 330 of the organic light-emitting display apparatus according to one or more exemplary embodiments of the present invention may be about 0.5 GPa to about 10 GPa.

The modulus of elasticity of the planarization layer 330 denotes a ratio of stress and deformation, and is a numerical value indicating a hardness (or a softness) of a material.

Because the planarization layer 330 of the organic light-emitting display apparatus according to one or more exemplary embodiments of the present invention has a high modulus of elasticity, the planarization layer 330 has a high viscosity and a high hardness to have the effects described above.

The hardness of the planarization layer 330 of the organic light-emitting display apparatus according to one or more exemplary embodiments of the present invention is about 0.1 GPa to about 5 GPa, and the planarization layer 330 includes the high viscosity silicone-based organic material, and thus, the planarization layer 330 may include particle-shaped materials.

When the planarization layer includes a material having a low viscosity, such as the acryl-based material of the planarization layer of the conventional organic light-emitting display apparatus, particle-shaped materials may not be included in the planarization layer. However, because the planarization layer 330 of the organic light-emitting display apparatus according to one or more exemplary embodiments of the present invention has a high viscosity, particle-shaped materials may be included in the planarization layer 330.

The particle-shaped materials included in the planarization layer 330 may be a scatter material and/or inorganic particles.

When the particle-shaped scatter material is included in the planarization layer 330, light is scattered, and thus, the emission efficiency may be improved.

The planarization layer 330 of the organic light-emitting display apparatus according to one or more exemplary embodiments of the present invention may include the combination of the high strength silicone-based organic material and the inorganic particles.

Also, the planarization layer 330 may include phenyl-based silicone, or polydimethylsiloxane including silsesquioxane.

However, materials of the planarization layer 330 are not limited thereto and may include any material which is a high strength silicone-based organic material and has a hardness of about 0.1 GPa to about 5 GPa.

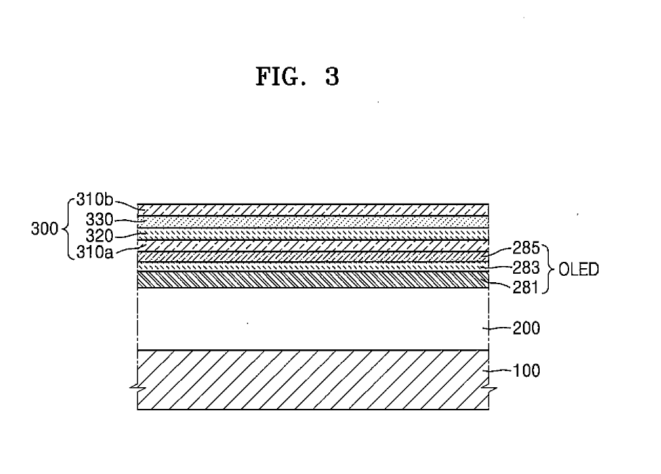

FIG. 3 is a cross-sectional view of an organic light-emitting display apparatus according to one or more exemplary embodiments of the present invention.

The thin film encapsulation portion 300 of the organic light-emitting display apparatus according to one or more exemplary embodiments of the present invention may further include an organic layer 320 between the first inorganic layer 310a and the planarization layer 330.

The organic layer 320 may include various organic materials, such as an acryl-based material, and may absorb stress of the first and second inorganic layers 310a and 310b to make the first and second inorganic layers 310a and 310b flexible.

The organic layer 320 may include a polymer. For example, the organic layer 320 may be a single layer or stacked layers including any one of polyethylene terephthalate, polyimide, polycarbonate, epoxy, polyethylene, and/or polyacrylate. For example, the organic layers may include polyacrylate. In more detail, the organic layers may include a polymerized monomer composition including a diacrylate-based monomer and/or a triacrylate-based monomer. The monomer composition may further include a monoacrylate-based monomer. Also, the monomer composition may further include a photoinitiator, such as TPO, but the present invention is not limited thereto.

In the conventional organic light-emitting display apparatuses, the thin film encapsulating layer does not include the planarization layer including the silicone-based material according to one or more exemplary embodiments of the present invention, and is formed by alternately stacking an inorganic layer and an organic layer. As such, the organic layer may absorb all high stress applied to the inorganic layer, causing a curl in the organic light-emitting display apparatus, which may lead to reduced instrumental strength reliability.

However, the thin film encapsulation portion 300 of the organic light-emitting display apparatus according to one or more exemplary embodiments of the present invention includes the first inorganic layer 310a, the organic layer 320, the planarization layer 330, and the second inorganic layer 310b. Thus, the organic layer 320 formed of an organic material provides the flexibility of the thin film encapsulation portion 300. Also, the planarization layer 330 includes a high strength and a high viscosity material, and thus, formation of a wrinkle, a haze, a fracture, etc. may be prevented, or the likelihood thereof may be reduced.

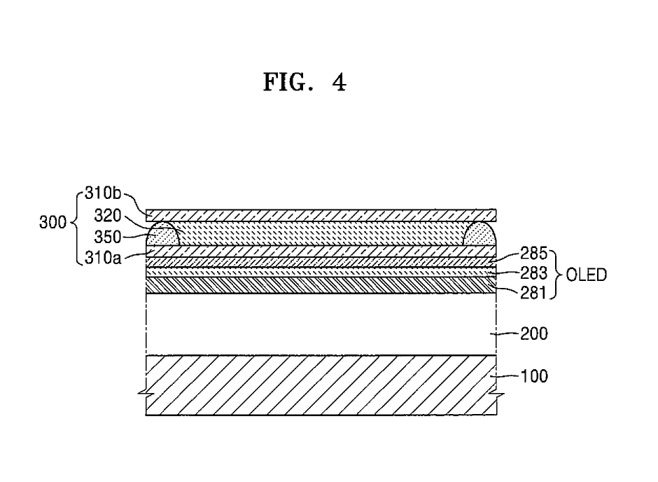

FIG. 4 is a cross-sectional view of an organic light-emitting display apparatus according to one or more exemplary embodiments of the present invention.

The thin film encapsulation portion 300 of the organic light-emitting display apparatus may include the first inorganic layer 310a, the organic layer 320, and the second inorganic layer 310b, and may further include a barrier (or dam or planarization dam) 350 between the first inorganic layer 310a and the organic layer 320.

The planarization dam 350 may have the same or substantially the same characteristics and functions as the planarization layer 330 of FIG. 2, but may have a different shape from the planarization layer 330. That is, the planarization dam 350 corresponds to the planarization layer 330 formed as a dam (or barrier) shape, and may include a silicon-based material having a high strength and a high viscosity.

Also, the planarization dam 350 may be formed to have a hardness of about 0.1 GPa to about 5 GPa and a modulus of elasticity of about 0.5 GPa to about 10 GPa.

In the conventional thin film encapsulating structure of the organic light-emitting display apparatus in which an inorganic layer and an organic layer are alternately stacked, the organic layer includes an acryl-based material having a low viscosity, and thus, the organic layer has a thickness that is no greater than 10 μm.

However, in the organic light-emitting display apparatus according to one or more exemplary embodiments of the present invention, the planarization dam 350 formed of the high viscosity silicone-based material may be formed on the first inorganic layer 310b to have a predetermined thickness, and the organic layer 320 may be formed on the planarization dam 350.

Accordingly, in the organic light-emitting display apparatus according to one or more embodiments of the present invention, the planarization dam 350 between the first inorganic layer 310a and the second inorganic layer 310b, and the organic layer 320 may be formed to have relatively large thicknesses.

Also, because the organic light-emitting display apparatus includes the planarization dam 350, when the organic layer 320 having a low viscosity is formed, the organic layer 320 may be prevented from flowing to the outside (or the likelihood thereof may be reduced).

In some embodiments, as illustrated in FIG. 4, the planarization dam 350 may be formed as a half circle on both ends of the inorganic layer 310a. However, the present invention is not limited thereto.

As described above, according to one or more of the above exemplary embodiments, because the strength and the viscosity of the thin film encapsulation portion are increased, the reliability of the organic light-emitting diode may be improved without forming a plurality of planarization layers, and occurrences of wrinkles and/or curling may be prevented or reduced.

It should be understood that exemplary embodiments described herein should be considered in a descriptive sense and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims and their equivalents.

What is claimed is:

1. An organic light-emitting display apparatus comprising:
a substrate;
an organic light-emitting diode on the substrate; and
a thin film encapsulation portion on the organic light-emitting diode and comprising:
a first inorganic layer;
a planarization layer comprising a silicone-based organic material; and
a second inorganic layer,
wherein a hardness of the planarization layer is about 0.1 GPa to about 5 GPa.

2. The organic light-emitting display apparatus of claim 1, wherein a modulus of elasticity of the planarization layer is about 0.5 GPa to about 10 GPa.

3. The organic light-emitting display apparatus of claim 1, wherein a thickness of the planarization layer is about 0.01 mm to about 0.1 mm.

4. The organic light-emitting display apparatus of claim 1, wherein the planarization layer comprises particle-shaped materials.

5. The organic light-emitting display apparatus of claim 4, wherein the particle-shaped materials are inorganic materials.

6. The organic light-emitting display apparatus of claim 4, wherein the particle-shaped materials are scatter materials.

7. The organic light-emitting display apparatus of claim 1, wherein the planarization layer comprises phenyl-based silicone.

8. The organic light-emitting display apparatus of claim 1, wherein the planarization layer comprises polydimethylsiloxane comprising silsesquioxane.

9. The organic light-emitting display apparatus of claim 1, wherein the thin film encapsulation portion further comprises an organic layer between the first inorganic layer and the planarization layer, the organic layer comprising an acryl-based material.

10. The organic light-emitting display apparatus of claim 1, wherein the planarization layer comprises a planarization dam at both ends of the first inorganic layer,
wherein the thin film encapsulation portion further comprises an organic layer between the planarization dam and the second inorganic layer, the organic layer comprising an acryl-based material.

11. An organic light-emitting display apparatus comprising:
a substrate;
an organic light-emitting diode on the substrate; and
a thin film encapsulation portion on the organic light-emitting diode and comprising:
a first inorganic layer;
a planarization layer comprising a silicone-based organic material; and
a second inorganic layer,
wherein a modulus of elasticity of the planarization layer is about 0.5 GPa to about 10 GPa.

12. An organic light-emitting display apparatus comprising:
a substrate;
an organic light-emitting diode on the substrate; and
a thin film encapsulation portion on the organic light-emitting diode and comprising:
a first inorganic layer;
a planarization layer comprising a silicone-based organic material; and
a second inorganic layer,
wherein a modulus of elasticity of the planarization layer is about 0.5 GPa to about 10 GPa, and
wherein a hardness of the planarization layer is about 0.1 GPa to about 5 GPa.

13. An organic light-emitting display apparatus comprising:
a substrate;
an organic light-emitting diode on the substrate; and
a thin film encapsulation portion on the organic light-emitting diode and comprising:
a first inorganic layer;
a second inorganic layer; and
a planarization dam between the first and second inorganic layers and comprising a high strength silicone-based organic material, wherein a hardness of the planarization dam is about 0.1 GPa to about 5 GPa.

14. The organic light-emitting display apparatus of claim 13, wherein a modulus of elasticity of the planarization dam is about 0.5 GPa to about 10 GPa.

15. The organic light-emitting display apparatus of claim 13, wherein the thin film encapsulation portion further comprises an organic layer between the planarization dam and the second inorganic layer, and
the organic layer comprises an acryl-based material.
